(19) United States
(12) Patent Application Publication
(10) Pub. No.: US 2024/0324479 A1
(43) Pub. Date: Sep. 26, 2024

(54) SWITCH DEVICE AND MEMORY UNIT

(71) Applicant: SONY SEMICONDUCTOR SOLUTIONS CORPORATION, KANAGAWA (JP)

(72) Inventors: MINORU IKARASHI, TOKYO (JP); SEIJI NONOGUCHI, KANAGAWA (JP)

(21) Appl. No.: 18/261,223

(22) PCT Filed: Dec. 24, 2021
(86) PCT No.: PCT/JP2021/048370

§ 371 Date: Jul. 12, 2023

(30) Foreign Application Priority Data
Jan. 20, 2021 (JP) 2021-007528

(51) Int. Cl. H10N 70/00; H10B 63/00; H10N 70/20

(52) U.S. Cl. CPC H10N 70/882; H10B 63/84; H10N 70/231; H10N 70/841; H10N 70/861

(57) ABSTRACT

A switch device of one embodiment of the present disclosure includes a first electrode, a second electrode disposed to be opposed to the first electrode, and a switch layer provided between the first electrode and the second electrode and including a first element selected from germanium and silicon, a second element selected from arsenic, phosphorus, and antimony, and a third element selected from selenium and tellurium. The switch layer includes at least one first layer and at least one second layer that are stacked. The first layer includes at least one kind of the second element and at least one kind of the third element, includes the third element in a range of 50 atomic % or more and 80 atomic % or less in composition ratio, and is negative in temperature dependence of a threshold voltage. The second layer includes at least one kind of the first element and at least one kind of the third element, includes the first element in a range of 20 atomic % or more and 50 atomic % or less in composition ratio, and is positive in temperature dependence of the threshold voltage.

### TECHNICAL FIELD

The present disclosure relates to a switch device including a chalcogenide material, and a memory unit including the switch device.

### BACKGROUND ART

There is a long history of research into a breakdown phenomenon of insulators, including oxides and nitrides, and semiconductors. Oxides and nitrides form ionic bond networks, and in many cases, an occurrence of the breakdown phenomenon means physical destruction of a device. A breakdown mechanism that determines a threshold electric field is referred to as electro-thermal breakdown, because both electric field and temperature are involved therein. For example, in Non-Patent Literature 1, it is presumed that Poole-Frenkel conduction is a major contributor to a leakage current characteristic of silicon nitride, and deriving of the threshold electric field is also conducted.

In contrast, compounds including any of chalcogen elements excluding oxygen form covalent bond networks, and have high resistance to a breakdown phenomenon caused by heat. This is evidence that a phase-change memory is not physically destructed even if a chalcogenide phase-change material undergoes such thermal shock as to exceed its melting point. For example, in Non-Patent Literature 2, it is reported that an ambient temperature dependence of a threshold voltage of gallium tellurium (Ga₂Te₃) monocrystal that is relatively low in trap density is in agreement with a result of Non-Patent Literature 1.

### CITATION LIST

### Non-Patent Literature

Non-Patent Literature 1: S. M. Sze, J. Appl. Phys., 38, 2951 (1967) Non-Patent Literature 2: S. I. Aliev, G. M. Niftiev, F. I. Pliev, and B. G. Tagiev, Sov. Phys. Semicond., 13, 340 (1979)

### SUMMARY OF THE INVENTION

Incidentally, regarding a cross-point memory cell array, it is desired to improve integration efficiency of memory cells in order to achieve a larger capacity.

It is desirable to provide a switch device and a memory unit that each make it possible to improve integration efficiency of memory cells.

A first switch device of one embodiment of the present disclosure includes a first electrode, a second electrode disposed to be opposed to the first electrode, and a switch layer provided between the first electrode and the second electrode and including a first element selected from germanium and silicon, a second element selected from arsenic, phosphorus, and antimony, and a third element selected from selenium and tellurium. The switch layer includes at least one first layer and at least one second layer that are stacked. The first layer includes at least one kind of the second element and at least one kind of the third element, includes the third element in a range of 50 atomic % or more and 80 atomic % or less in composition ratio, and is negative in temperature dependence of a threshold voltage. The second layer includes at least one kind of the first element and at least one kind of the third element, includes the first element in a range of 20 atomic % or more and 50 atomic % or less in composition ratio, and is positive in temperature dependence of the threshold voltage.

A second switch device of one embodiment of the present disclosure includes a first electrode, a second electrode disposed to be opposed to the first electrode, and a switch layer having different diameters in a stacking direction.

A memory unit of one embodiment of the present disclosure includes multiple memory cells. Each of the memory cells includes a memory device and the first switch device of above-described embodiment of the present disclosure directly coupled to the memory device.

In the first switch device of one embodiment of the present disclosure, the second switch device of one embodiment of the present disclosure, and the memory unit of one embodiment of the present disclosure, the switch layer including the first element selected from germanium and silicon, the second element selected from arsenic, phosphorus, and antimony, and the third element selected from selenium and tellurium is provided between the first electrode and the second electrode. The switch layer of the first switch device among them includes at least one first layer and at least one second layer that are stacked. The first layer includes at least one kind of the second element and at least one kind of the third element, includes the third element in the range of 50 atomic % or more and 80 atomic % or less in composition ratio, and is negative in temperature dependence of the threshold voltage. The second layer includes at least one kind of the first element and at least one kind of the third element, includes the first element in the range of 20 atomic % or more and 50 atomic % or less in composition ratio, and is positive in temperature dependence of the threshold voltage. The switch layer of the second switch device has different diameters in the stacking direction. This reduces dependence, of the threshold voltage and a threshold electric field at which the switch device switches between on and off states, on an ambient temperature.

### BRIEF DESCRIPTION OF DRAWINGS

FIG. 1 is a schematic cross-sectional diagram illustrating an example of a configuration of a switch device according to a first embodiment of the present disclosure.

FIG. 2 is a diagram illustrating an example of an outline configuration of a memory cell array of the present disclosure.

FIG. 3 is a characteristic diagram illustrating a mean coordination number dependence of irreversible enthalpy.

FIG. 4 is a ternary diagram illustrating a state of a GeAsSe glass.

FIG. 5 is a ternary diagram illustrating a composition dependence of a Debye temperature of the GeAsSe glass.

FIG. 6 is a ternary diagram illustrating a temperature dependence of a threshold voltage of the GeAsSe glass.

FIG. 7 is a schematic diagram of an experimental apparatus used in Example 1.

FIG. 8 is a characteristic diagram illustrating a relationship between a current density and an electric field in Example 1.

FIG. 9 is a ternary diagram of the GeAsSe glass illustrating a material composition matching Example 1.

FIG. 10 is a schematic cross-sectional diagram illustrating another example of the configuration of the switch device according to the first embodiment of the present disclosure.

FIG. 11 is a schematic cross-sectional diagram illustrating another example of the configuration of the switch device according to the first embodiment of the present disclosure.

FIG. 12 is a schematic cross-sectional diagram illustrating another example of the configuration of the switch device according to the first embodiment of the present disclosure.

FIG. 13 is a schematic cross-sectional diagram illustrating another example of the configuration of the switch device according to the first embodiment of the present disclosure.

FIG. 14 is a schematic cross-sectional diagram illustrating another example of the configuration of the switch device according to the first embodiment of the present disclosure.

FIG. 15 is a schematic cross-sectional diagram illustrating an example of a configuration of a memory device.

FIG. 16 is a schematic cross-sectional diagram illustrating an example of a configuration of a switch device according to a second embodiment of the present disclosure.

FIG. 17 is a characteristic diagram illustrating a size dependence of the Debye temperature.

FIG. 18 is a schematic diagram of an experimental apparatus used in Example 2.

FIG. 19 is a schematic cross-sectional diagram illustrating another example of the configuration of the switch device according to the second embodiment of the present disclosure.

FIG. 20 is a schematic cross-sectional diagram illustrating another example of the configuration of the switch device according to the second embodiment of the present disclosure.

FIG. 21 is a schematic cross-sectional diagram illustrating another example of the configuration of the switch device according to the second embodiment of the present disclosure.

FIG. 22 is a schematic cross-sectional diagram illustrating another example of the configuration of the switch device according to the second embodiment of the present disclosure.

FIG. 23 is a diagram illustrating an example of an outline configuration of a memory cell array of a modification example of the present disclosure.

FIG. 24 is a diagram illustrating another example of the outline configuration of the memory cell array of the modification example of the present disclosure.

FIG. 25 is a diagram illustrating another example of the outline configuration of the memory cell array of the modification example of the present disclosure.

FIG. 26 is a diagram illustrating another example of the outline configuration of the memory cell array of the modification example of the present disclosure.

### MODES FOR CARRYING OUT THE INVENTION

In the following, embodiments of the present disclosure will be described in detail with reference to the drawings. The following description is a specific example of the present disclosure, and the present disclosure is not limited to the following aspects. In addition, the present disclosure is not limited to the arrangement, dimensions, dimensional ratios, and the like of each component illustrated in each drawing. The order in which the description is given is as follows.
1. First Embodiment (an example of a switch device including a switch layer having a stacked structure including a layer in which a temperature dependence of a threshold voltage is negative and a layer in which the temperature dependence of the threshold voltage is positive)
   1-1. Configuration of Switch Device
   1-2. Configuration of Memory Cell Array
   1-3. Workings and Effects
2. Second Embodiment (an example of a switch device including a switch layer having different diameters in a stacking direction)
3. Modification Example (an example of a memory cell array having a three-dimensional structure)

### 1. First Embodiment

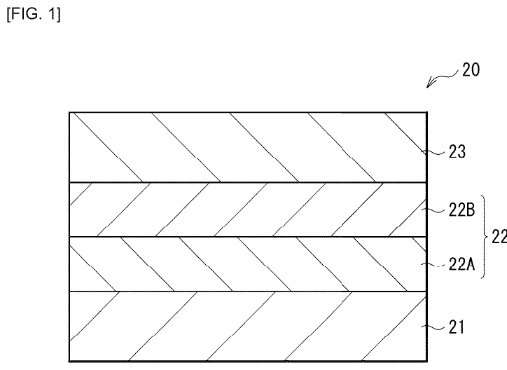

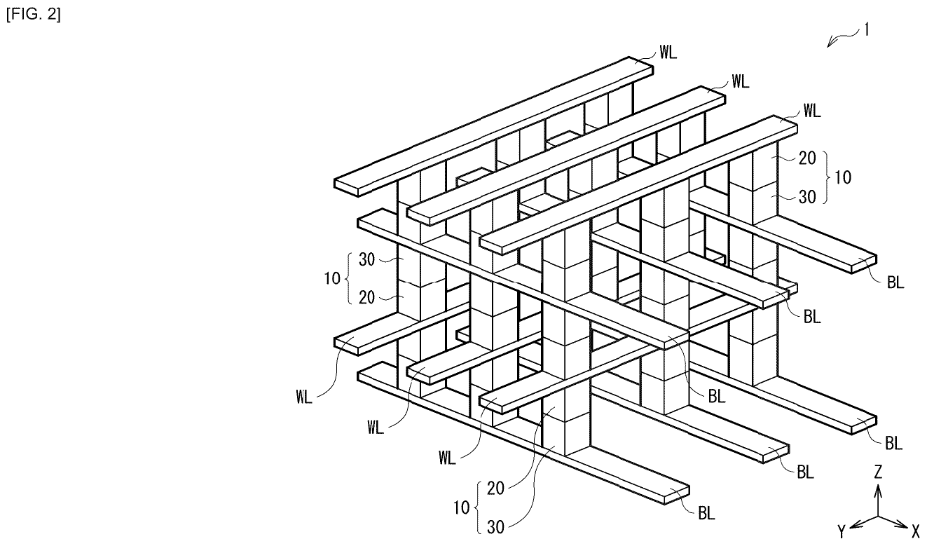

FIG. 1 schematically illustrates an example of a cross-sectional configuration of a switch device (a switch device 20) according to a first embodiment of the present disclosure. This switch device 20 is provided to selectively operate, for example, any memory device (a memory device 30, see FIG. 15, for example) among multiple memory devices provided in a memory cell array 1 having a so-called cross-point array structure illustrated in FIG. 2. The switch device 20 is coupled in series to the memory device 30 (specifically, a memory layer 32), and includes a lower electrode 21, a switch layer 22, and an upper electrode 23 in this order.

The switch device 20 of the present embodiment includes the switch layer 22 including a first element selected from germanium and silicon (Si), a second (Ge) element selected from arsenic (As), phosphorus (P), and antimony (Sb), and a third element selected from selenium (Se) and tellurium (Te). The switch layer 22 has a stacked structure in which at least one first layer 22A and at least one second layer 22B are stacked. The first layer 22A includes, among the three kinds of elements described above, at least one kind of the second element and at least one kind of the third element, includes the third element in a range of 50 atomic % or more and 80 atomic % or less in composition ratio, and has a negative temperature dependence of a threshold voltage. The second layer 22B includes, among the three kinds of elements described above, at least one kind of the first element and at least one kind of the third element, includes the first element in a range of 20 atomic % or more and 50 atomic % or less in composition ratio, and has a positive temperature dependence of the threshold voltage.

### 1-1. Configuration of Switch Device

The switch device 20 includes the lower electrode 21, the switch layer 22, and the upper electrode 23 that are stacked in this order, as described above. A detailed description will be given below of each component included in the switch device 20.

The lower electrode 21 corresponds to a specific example of a “first electrode” in the present disclosure. The lower electrode 21 may include a wiring line material to be used in a semiconductor process, for example. Specifically, the lower electrode 21 may include, for example, tungsten (W), tungsten nitride (WN), titanium nitride (TiN), copper (Cu), aluminum (Al), molybdenum (Mo), tantalum (Ta), tantalum nitride (TaN), silicide, or the like. In a case where the lower electrode 21 includes a material that can cause ion conduction in an electric field, such as Cu, a front surface of the lower electrode 21 may be coated with a material that is unlikely to cause ion conduction or thermal diffusion. Examples of the material that is unlikely to cause ion conduction or thermal diffusion include W, WN, TIN, TaN, titanium tungsten (TiW), titanium tungsten nitride (TiWN), and the like.

The switch layer 22 changes into a low-resistance state by making an applied voltage higher than or equal to a predetermined threshold voltage (a switching threshold voltage), and changes into a high-resistance state by making the applied voltage lower than the switching threshold voltage. In addition, the switch layer 22 has a negative differential resistance characteristic and, when the voltage applied to the switch device 20 exceeds the predetermined threshold voltage (the switching threshold voltage), passes a several orders of magnitude larger electric current therethrough.

In addition, the switch layer 22 is such one that an amorphous structure of the switch layer 22 stably remains regardless of application of a voltage pulse or a current pulse via the lower electrode 21 and the upper electrode 23 from an unillustrated power supply circuit (a pulse applying means). It is to be noted that the switch layer 22 does not perform such a memory operation as to allow a conduction path formed by movement of ions caused by voltage application to remain after erasure of the applied voltage.

The switch layer 22 of the present embodiment includes, as described above, the first element selected from Ge and Si, the second element selected from As, P, and Sb, and the third element selected from Se and Te. The switch layer 22 has a stacked structure in which at least one first layer 22A and at least one second layer 22B are stacked. The first layer 22A has the negative temperature dependence of the threshold voltage, and the second layer 22B has the positive temperature dependence of the threshold voltage.

As described above, typically, the compounds including any of chalcogen elements (sulfur (S), Se, and Te) excluding oxygen (O) form covalent bond networks, and have high resistance to the breakdown phenomenon caused by heat. A general composition of a chalcogenide glass which is an example of the compound including a chalcogen element (a chalcogenide phase-change material) is expressed as Ge(Si)ₓAs(P, Sb)_{y}Se(Te)_{1-x-y}. Valences of Ge(Si), As(P, Sb), and Se(Te) are 4, 3, and 2, respectively, and the coordination numbers thereof are assumed to correspond to the valences. A mean coordination number (MCN) is defined by mathematical expression (1) below.

$$\begin{matrix}[ Math . 1 ] & \\ MCN = 4 x + 3 y + 2 ( 1 - x - y ) & ( 1 )\end{matrix}$$

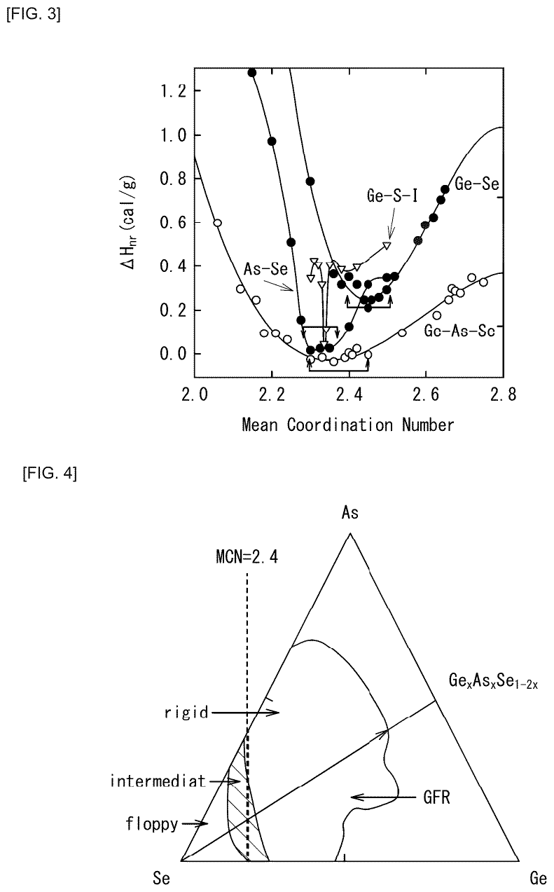

An optimum composition of a GeAsSe glass which is known as an infrared transmitting glass has been investigated in detail by modulated temperature differential scanning calorimeter (MDSC) analysis (Literature 1: P. Bloolehand, D. G. Georgiiev, and B. Goodman, J. Opt. and Adv. Mater., 3, 703 (2001)). FIG. 3 illustrates a mean coordination number dependence of irreversible enthalpy (ΔHₙᵣ). An intermediate phase that minimizes the irreversible enthalpy (ΔHₙᵣ) lies around a mean coordination number of 2.4, and is considered to be a region that undergoes the smallest change over time. The switch device and the memory device repeat such a behavior that a glass transition temperature is exceeded. Accordingly, in a case where it is aimed to improve degradation in optical characteristic, the intermediate phase region illustrated in FIG. 4 provides an optimum composition. It is to be noted that GFR in FIG. 4 corresponds to a glass forming region, a floppy region corresponds to a soft glass, and a rijid region corresponds to a rigid glass.

The chalcogenide phase-change material increases in trap density if atomic vacancies or atomic deficiencies become extremely high. The increase in trap density leads to overlapping of scalar potentials caused by a trap level, resulting in that an effective barrier height is determined regardless of the shape of the scalar potential. Such an extreme conduction state is called Poole-Frenkel conduction. Many of practical switch devices and memory devices are of the Poole-Frenkel conduction type, and a current density (j) is expressed by mathematical expression (2) below. A proportionality constant (a function of temperature) η in mathematical expression (2) is defined by mathematical expression (2′) below. It is to be noted that an average inter-trap spacing is Δz (Literature 2: D. Ielmini and Y. Zhang, IEDM Tech. Dig., 136 (2006)), and the current density of the Poole-Frenkel conduction type has a characteristic of being relatively less susceptible to a dielectric constant of the chalcogenide phase-change material.

$$\begin{matrix}[ Math . 2 ] & \\ j = A ( T ) exp ( - \frac{{ϕ}_{B} - Fd / η}{{V}_{t}} ) F ( A / {cm}^{2} ) & ( 2 )\end{matrix}$$

$$η = \frac{2 d}{Δ z} \qquad ( {2}^{′} )$$

where: A(T) represents proportionality constant (function of temperature (A/cm²)), ϕB represents barrier height (eV), F represents electric field (MV/cm); and d represents film thickness.

If a temperature dependence of a threshold electric field (Fₜₕ) of the chalcogenide phase-change material is determined in accordance with a procedure similar to that in Non-Patent Literature 1, mathematical expression (3) below results.

$$\begin{matrix}[ Math . 3 ] & \\ {F}_{th} = \frac{η}{d} [ {ϕ}_{B} - CT ] & ( 3 )\end{matrix}$$

Parameter (function of temperature) C is expressed by mathematical expression (4) below.

$$\begin{matrix}[ Math . 4 ] & \\ C = \frac{{k}_{B}}{e} ln [ \frac{{k}_{E} A ( T ) {R}_{n}}{e} \frac{η {ϕ}_{B} - {F}_{th} d}{η {V}_{t}^{3}} {F}_{th}^{3} \times {S}_{f} d ] & ( 4 )\end{matrix}$$

where k_{B} represents Boltzmann constant, A(T) represents proportionality constant (A/cm²), ϕB represents barrier height (eV), Fₜₕ represents threshold electric field (MV/cm), d represents film thickness, and Vt represents thermal voltage.

Because the threshold electric field (Fₜₕ) itself is included in the definition of the parameter C, the threshold electric field (Fₜₕ) is obtained only by iteratively calculating mathematical expressions (3) and (4) as recurrence equations. Although there is a difference in the power of the electric field (F), mathematical expressions (3) and (4) are not essentially different from the mathematical expressions of the temperature dependence of the threshold electric field (Fₜₕ) of an insulator such as an oxide or a nitride and the parameter (function of temperature) C, and it is easily considered, on the basis of existing common knowledge, that the parameter C is always positive and similarly an ambient temperature dependence of the threshold electric field (Fₜₕ) becomes negative.

Next, a description is given of a method of causing the ambient temperature dependence of the threshold electric field (Fₜₕ) of the chalcogenide phase-change material to be positive. It is demanded that memory cell arrays be increased in capacity, and accordingly, switch devices and memory devices have been reduced in film thickness to a nanometer size. Assume that a thermal resistance (Rh) of the thin film of the nanometer-sized chalcogenide phase-change material is approximately expressed by mathematical expression (5) below.

$$\begin{matrix}[ Math . 5 ] & \\ {R}_{h} \approx \frac{d}{κ {S}_{f}} & ( 5 )\end{matrix}$$

where κ represents thermal conductivity.

Substituting mathematical expression (5) into mathematical expression (4) yields mathematical expression (6) below.

$$\begin{matrix}[ Math . 6 ] & \\ C = \frac{{k}_{B}}{e} ln [ \frac{{k}_{B} A ( T )}{e} \frac{η {ϕ}_{B} - {F}_{th} d}{η {V}_{t}^{2}} {F}_{th}^{2} \times \frac{{d}^{2}}{κ} ] & ( 6 )\end{matrix}$$

where k_{B} represents Boltzmann constant, A(T) represents proportionality constant (A/cm²), ϕB represents barrier height (eV), Fₜₕ represents threshold electric field (MV/cm), d represents film thickness, Vt represents thermal voltage, and κ represents thermal conductivity.

The proportionality constant (n) has a relatively small composition dependence. The barrier height (ϕ_{B}) experimentally has a value of about ¼ of a bandgap (Eg) and has a composition dependence, but is not so effective as to reverse the sign of the parameter C. In terms of device design, what is most easily changeable is the film thickness (d); however, from the viewpoint of maintaining the threshold voltage (Vₜₕ) at its design value, it is difficult to extremely reduce the film thickness. Therefore, what is selectable is the thermal conductivity (κ). A condition for causing the ambient temperature dependence of the threshold electric field (Fₜₕ) to be positive is that the natural logarithm inside the brackets on the right side of mathematical expression (6) above is smaller than 1, that is, mathematical expression (7) below.

$$\begin{matrix}[ Math . 7 ] & \\ \frac{{k}_{B} A ( T )}{e} \frac{η {ϕ}_{B} - {F}_{th} d}{η {V}_{t}^{2}} {F}_{th}^{3} \times \frac{{d}^{2}}{κ} < 1 & ( 7 )\end{matrix}$$

where k_{B} represents Boltzmann constant, A(T) represents proportionality constant (A/cm²), ϕ_{B} represents barrier height (eV), Fₜₕ represents threshold electric field (MV/cm), d represents film thickness, Vt represents thermal voltage, and κ represents thermal conductivity.

If the natural logarithm inside the brackets becomes smaller than 1, the sign of the parameter C is reversed, and the threshold electric field (Fₜₕ) increases as the ambient temperature rises. As is apparent from mathematical expression (7) above, the smaller the film thickness, the more easily the effect is exhibited; however, as described above, there is a limit to reducing the film thickness. It is known that the thermal conductivity (κ) is proportional to the third power of a Debye temperature (T_{D}) of the material, as expressed by mathematical expression (8) below (Literature 3: J. Lonergan, C. Smith, D. McClane, and K. Richardson, J. Appl. Phys., 120, 145101 (2016)).

$$\begin{matrix}[ Math . 8 ] & \\ κ = {α}_{G} \frac{{T}_{D}^{3}}{T} & ( 8 )\end{matrix}$$

where α_{G} represents proportionality constant including Gruneisen parameter γ_{G}.

The Debye temperature (T_{D}) in a case where the general composition of the chalcogenide glass is expressed as Ge(Si)ₓAs(P, Sb)_{y}Se(Te)_{1-x-y} is, as indicated by mathematical expression (9) below, expressed as the product of a term dependent on composition and a term dependent on size (Literature 4: Y. Ma, K. Zhu and M. Li, Phys. Chem. Chem. Phys., 20, 27539 (2018)).

$$\begin{matrix}[ Math . 9 ] & \\ {T}_{D} ( x , y , D ) = {T}_{D} ( x , y ) \sqrt{1 - \frac{{α}_{S}}{D}} & ( 9 )\end{matrix}$$

where D represents diameter of the thin film, and as represents proportionality constant including dimensionless parameter β_{S}.

The thermal conductivity (κ) of a bulk material is proportional to a phonon mean free path (Literature 5: ISBN-13:978-4621076538, (2005)). A reason why the Debye temperature (T_{D}) depends on size is that the device size is less than or equal to the mean free path of phonons. To reduce the ambient temperature dependence of the threshold voltage (Vₜₕ) with a stacked film including at least two layers (layer A and layer B), it is sufficient that the thermal conductivity (κ) is so selected as to cancel out the ambient temperature dependence of a composite threshold voltage (Vₜₕ(A, B)) as indicated by mathematical expression (10) below.

$$\begin{matrix}[ Math . 10 ] & \\ {V}_{th} ( A , B ) = {F}_{th} ( A ) d ( A ) + {F}_{th} ( B ) d ( B ) & ( 10 )\end{matrix}$$

### Example 1

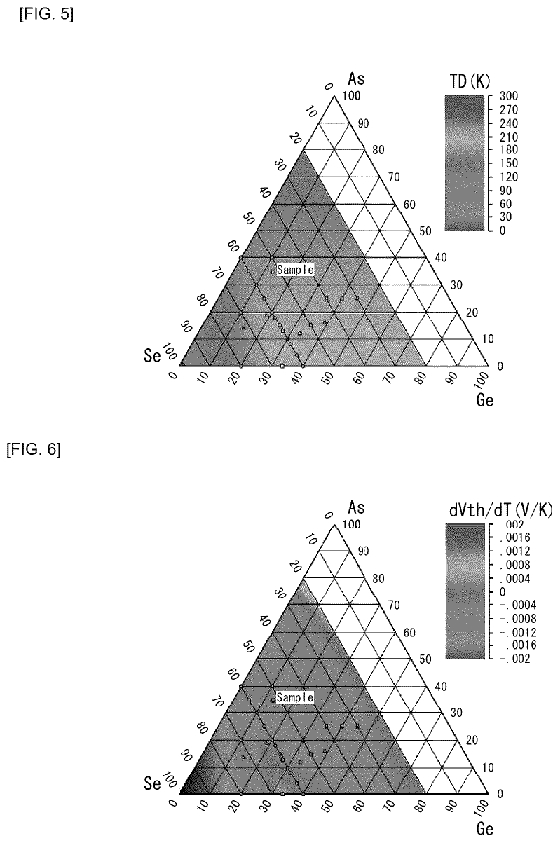

FIG. 5 is a ternary diagram of the Debye temperature (T_{D}) of a GeAsSe glass drawn on the basis of actual measurements. The Debye temperature (T_{D}) of an unknown composition was calculated back by using the Debye temperature (T_{D}) described in Literature 3 above and Lindemann's equation of melting (a melting point (Tm) is proportional to the square of the Debye temperature (T_{D})). FIG. 6 is a ternary diagram of a temperature dependence of the GeAsSe glass drawn on the basis of actual measurements. The threshold voltage (vₜₕ) at a location where no sample was present was estimated using the mean coordination number. A region where the Se composition is 20% or less was large in error, and illustration thereof is thus omitted.

In Example 1, layer A (the first layer 22A) as a layer having a negative temperature dependence of the threshold voltage and layer B (the second layer 22B) as a layer having a positive temperature dependence of the threshold voltage were formed in order by co-sputtering. The layer A had a composition ratio of As₄₀Se₆₀ and a film thickness (d_{A}) of 10 nm. The layer B had a composition ratio of Ge_{33.3}Se_{66.7} and a film thickness (d_{B}) of 20 nm.

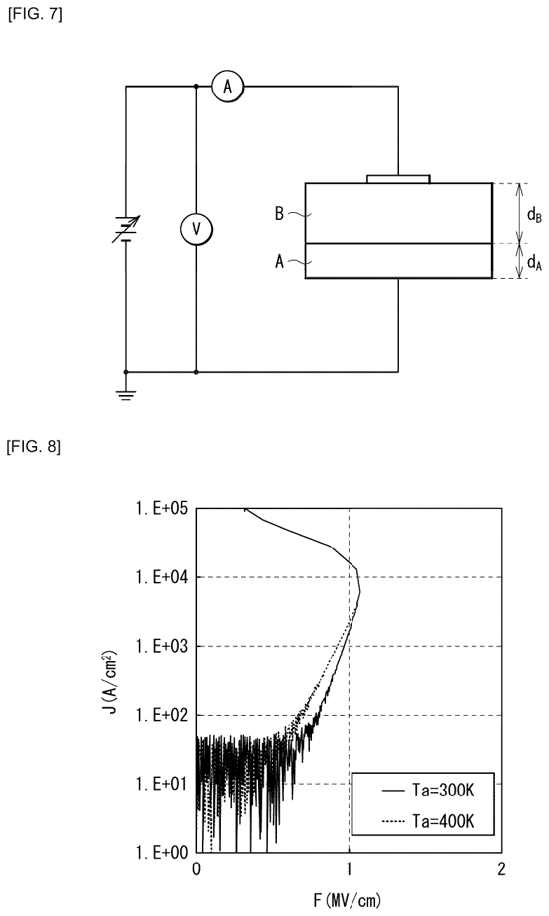

FIG. 7 schematically illustrates an experimental apparatus used in Example 1. FIG. 8 is a characteristic diagram illustrating a relationship between the current density (j) and the electric field (F) at ambient temperatures (Ta) of 300 K and 400 K around the layered film. From FIG. 8, it was found that there was no significant change in the relationship between the current density (j) and the electric field (F) between the ambient temperatures (Ta) of 300 K and 400 K. That is, it was found that stacking the layer A (the first layer 22A) having the negative temperature dependence of the threshold voltage and the layer B (the second layer 22B) having the positive temperature dependence of the threshold voltage makes it possible to reduce the temperature dependence of the composite threshold voltage of the stacked film.

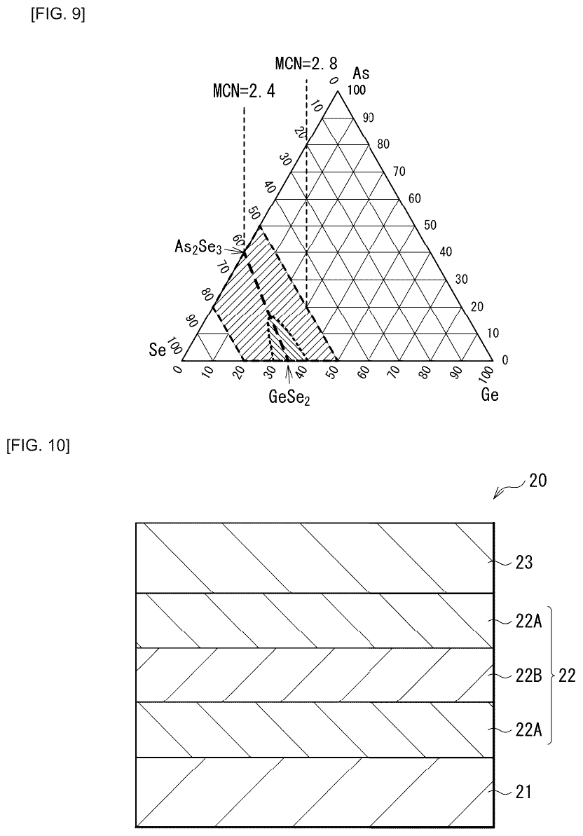

FIG. 9 is a ternary diagram of the GeAsSe glass illustrating a material composition that allows a result similar to that of Example 1 to be obtained. It is possible to form the layer (the first layer 22A) having the negative temperature dependence of the threshold voltage by selecting, among the first element, the second element, and the third element described above, at least one kind of the second element and at least one kind of the third element and further, allowing the third element to fall within a range of 50 atomic % or more and 80 atomic % or less in composition ratio. It is possible to form the layer (the second layer 22B) having the positive temperature dependence of the threshold voltage by selecting, among the first element, the second element, and the third element described above, at least one kind of the first element and at least one kind of the third element and further, allowing the first element to fall within a range of 20 atomic % or more and 50 atomic % or less in composition ratio. At this time, the first layer 22A and the second layer 22B each include the second element in a range of 0 atomic % or more and 50 atomic % or less in composition ratio.

The switch layer 22 may further include, as an impurity, at least one of boron (B), aluminum (Al), gallium (Ga), or indium (In) to the extent that the properties of the first layer 22A and the second layer 22B described above are not impaired. This improves the thermal conductivity (K) of the switch layer 22. Because the first layer 22A is generally p-type conductive, it is preferable to use, as a heat-transporting carrier, holes in a supplementary manner in addition to phonons.

The switch layer 22 preferably has a film thickness of 15 nm or more and 150 nm or less, for example. Of the switch layer 22, the first layer 22A preferably has a film thickness of 5 nm or more and 50 nm or less, for example, and the second layer 22B preferably has a film thickness of 10 nm or more and 100 nmm or less, for example.

The upper electrode 23 corresponds to a specific example of a “second electrode” in the present disclosure. The upper electrode 23 may include, for example, a known semiconductor wiring line material as with the lower electrode 21; however, it is preferable to use a stable material that does not react with the switch layer 22 even after undergoing post-annealing. Specifically, the upper electrode 23 may include tungsten (W), for example.

The switch device 20 has such a switching characteristic that while in an initial state, the switch device 20 has a high resistance value (is in a high-resistance state (off state)) and, when supplied with voltage, has a low resistance value (comes into a low-resistance state (on state)) at a certain voltage (the switching threshold voltage). Further, the switch device 20 is not kept in an on state because it comes back into the high-resistance state when the applied voltage is decreased to below the switching threshold voltage or when the application of voltage is stopped. That is, the switch device 20 is free of memory operations to be performed upon a phase change (between a non-crystalline phase (an amorphous phase) and a crystalline phase) of the switch layer 22 caused by application of a voltage pulse or a current pulse from an unillustrated power supply circuit (a pulse applying means) via the lower electrode 21 and the upper electrode 23.

Besides the above-described configuration of the switch device 20, the switch device 20 of the present embodiment may have the following configurations.

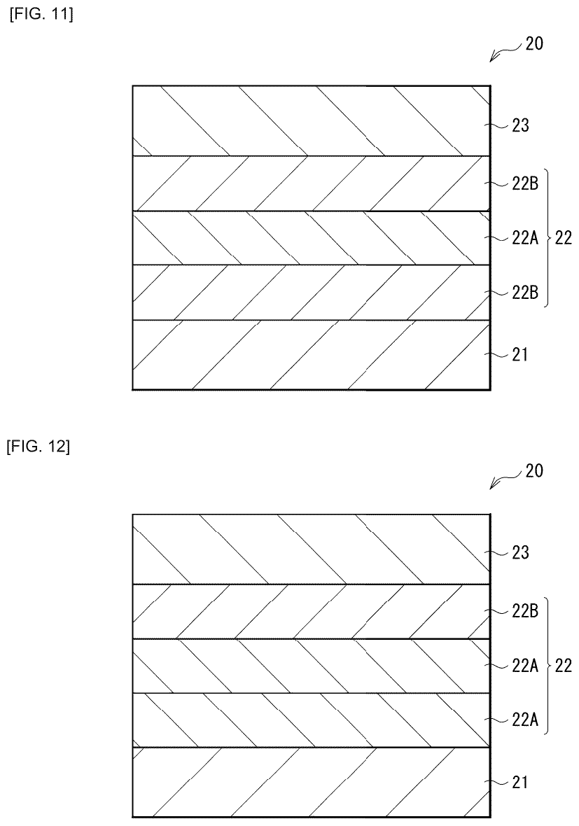

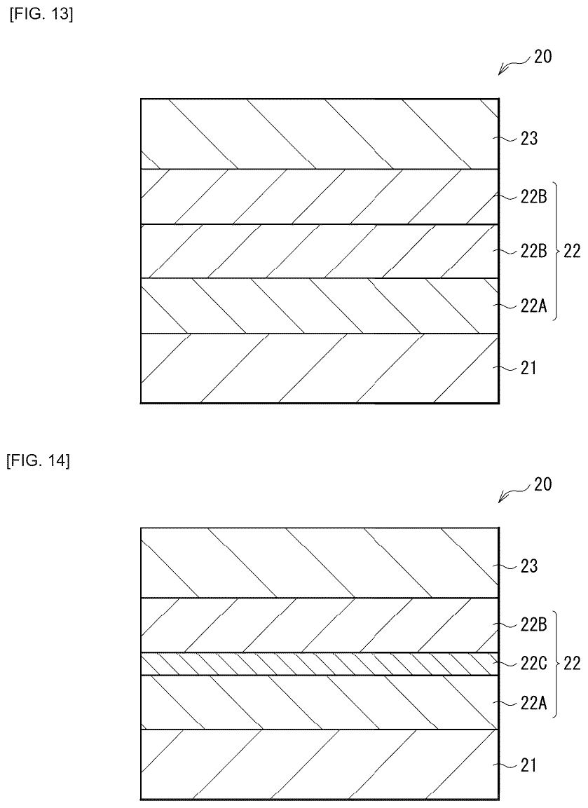

For example, the switch device 20 may have a configuration in which two or more first layers 22A and two or more second layers 22B configuring the switch layer 22 are stacked. For example, as illustrated in FIG. 10, the switch layer 22 may have a configuration in which the first layer 22A, the second layer 22B, and the first layer 22A are stacked in this order from the lower electrode 21 side. For example, as illustrated in FIG. 11, the switch layer 22 may have a configuration in which the second layer 22B, the first layer 22A, and the second layer 22B are stacked in this order from the lower electrode 21 side. For example, as illustrated in FIG. 12, the switch layer 22 may have a configuration in which two first layers 22A and the second layer 22B are stacked in this order from the lower electrode 21 side. For example, as illustrated in FIG. 13, the switch layer 22 may have a configuration in which the first layer 22A and two second layers 22B are stacked in this order from the lower electrode 21 side.

Further, the switch layer may include a layer other than the first layer 22A and the second layer 22B. For example, as illustrated in FIG. 14, a third layer 22C without any ambient temperature dependence of the threshold electric field (Fₜₕ) may be provided between the first layer 22A and the second layer 22B. In such a case, the third layer 22C satisfies mathematical expression (11) below. It is to be noted that the position of the third layer 22C is not limited to thereto. For example, the first layer 22A, the second layer 22B, and the third layer 22C may be stacked in this order from the lower electrode 21 side, or the third layer 22C, the first layer 22A, and the second layer 22B may be stacked in this order from the lower electrode 21 side.

$$\begin{matrix}[ Math . 11 ] & \\ \frac{{k}_{B} A ( T )}{e} \frac{η {ϕ}_{B} - {F}_{th} d}{η {V}_{t}^{2}} {F}_{th}^{2} \times \frac{{d}^{2}}{κ} = 1 & ( 11 )\end{matrix}$$

where k_{B} represents Boltzmann constant, A(T) represents proportionality constant (A/cm²), ϕ_{B} represents barrier height (eV), Fₜₕ represents threshold electric field (MV/cm), d represents film thickness, Vt represents thermal voltage, and K represents thermal conductivity.

### 1-2. Configuration of Memory Cell Array

FIG. 2 is a perspective representation of an example of a configuration of the memory cell array 1. The memory cell array 1 corresponds to a specific example of a “memory unit” in the present disclosure. The memory cell array 1 has the so-called cross-point array structure, and includes, for example, memory cells 10 disposed one at each of positions (cross-points) where word lines WL and bit lines BL are opposed to each other, as illustrated in FIG. 2. That is, the memory cell array 1 includes multiple word lines WL, multiple bit lines BL, and multiple memory cells 10 disposed one at each of the cross-points.

The word lines WL all extend in the same direction. The bit lines BL extend in the same direction that is a direction different from the extending direction of the word lines WL (for example, a direction orthogonal to the extending direction of the word lines WL). It is to be noted that the multiple word lines WL and the multiple bit lines BL are disposed in one or more layers, and may be divided to be disposed in multiple levels, for example.

For example, as illustrated in FIG. 2, in a case where the multiple word lines WL are divided to be disposed in multiple levels, the multiple bit lines BL are disposed between a first layer in which the multiple word lines WL are disposed and a second layer which is adjacent to the first layer and in which the multiple word lines WL are disposed. In a case where the multiple bit lines BL are divided to be disposed in multiple levels, the multiple word lines WL are disposed between a third layer in which the multiple bit lines BL are disposed and a fourth layer which is adjacent to the third layer and in which the multiple bit lines BL are disposed. That is, in a case where the multiple word lines WL and the multiple bit lines BL are divided to be disposed in respective multiple levels, the multiple word lines WL and the multiple bit lines BL are alternately disposed in the stacking direction of the memory cell array 1 (e.g., a Z-axis direction).

In this way, in the memory cell array 1, the multiple word lines WL and the multiple bit lines BL are disposed in one level or divided to be disposed in multiple levels on a substrate (unillustrated), and the memory cells 10 are disposed two-dimensionally or three-dimensionally at the respective cross-points. Furthermore, for example, a wiring line group electrically coupled to the word line WL and the bit line BL, a circuit to be used to couple the wiring line group and an external circuit to each other, etc. are provided on the substrate.

The memory cell 10 includes, for example, the switch device 20 and the memory device 30 described above. As described above, the memory cells 10 are disposed one at each of the cross-points between the word lines WL and the bit lines BL.

FIG. 15 schematically illustrates an example of a cross-sectional configuration of the memory device 30. The memory device 30 includes a lower electrode 31, the memory layer 32, and an upper electrode 33 that are stacked in this order.

As with the lower electrode 21 of the switch device 20, the lower electrode 31 may include a wiring line material to be used in a semiconductor process, for example. Specifically, the lower electrode 31 may include, for example, W, WN, TiN, Cu, Al, Mo, Ta, TaN, silicide, or the like. In a case where the lower electrode 31 includes a material that can cause ion conduction in an electric field, such as Cu, a front surface of the lower electrode 31 may be coated with a material that is unlikely to cause ion conduction or thermal diffusion. Examples of the material that is unlikely to cause ion conduction or thermal diffusion include W, WN, TIN, TaN, TiW, TiWN, and the like.

As with the switch layer 22 described above, the memory layer 32 includes a first element selected from Ge and Si, a second element selected from As, P, and Sb, and a third element selected from Se and Te. Furthermore, the memory layer 32 has a stacked structure in which at least one first layer 32A and at least one second layer 32B are stacked.

The first layer 32A corresponds to a specific example of a “third layer” in the present disclosure, and has the negative temperature dependence of the threshold voltage. It is possible to form the first layer 32A by selecting, among the first element, the second element, and the third element, at least one kind of the second element and at least one kind of the third element and further, allowing the third element to fall within the range of 50 atomic % or more and 80 atomic % or less in composition ratio.

The second layer 32B corresponds to a specific example of a “fourth layer” in the present disclosure, and has the positive temperature dependence of the threshold voltage. It is possible to form the second layer 32B by selecting, among the first element, the second element, and the third element, at least one kind of the first element and at least one kind of the third element and further, allowing the first element to fall within the range of 20 atomic % or more and 50 atomic % or less in composition ratio.

The memory layer 32 preferably has a film thickness of 15 nm or more and 150 nm or less, for example. Of the memory layer 32, the first layer 32A preferably has a film thickness of 5 nm or more and 50 nm or less, for example, and the second layer 32B preferably has a film thickness of 10 nm or more and 100 nmm or less, for example.

The upper electrode 33 may include, for example, a known semiconductor wiring line material as with the lower electrode 31: however, it is preferable to use a stable material that does not react with the memory layer 32 even after undergoing post-annealing. Specifically, the upper electrode 33 may include tungsten (W), for example.

It is to be noted that the memory device 30 may include a layer other than the memory layer 32 between the lower electrode 31 and the upper electrode 33. For example, an oxide layer including, for example, tantalum oxide or titanium oxide may be provided as an underlayer, an adhesion layer, a protective layer, or a diffusion-preventing layer.

In the memory cell 10, the switch device 20 and the memory device 30 are directly coupled to each other. In a case of configuring the memory cell 10 using the switch device 20 and the memory device 30 described above, the electrodes to be stacked on each other between the switch device 20 and the memory device 30 (e.g., the upper electrode 33 of the memory device 30 and the lower electrode 21 of the switch device 20) may be integrally formed as an intermediate electrode and may also serve as the upper electrode and the lower electrode of the respective devices.

Further, the electrodes to be disposed in a lowermost layer and an uppermost layer of the memory cell 10 (e.g., the lower electrode 31 of the memory device 30 and the upper electrode 23 of the switch device 20) may also serve as the word lines WL and the bit lines BL, or may be provided as electrodes separate from the word lines WL and the bit lines BL.

FIG. 2 illustrates an example in which the switch device 20 is disposed closer to the word line W, for example, and the memory device 30 is disposed closer to the bit line BL, for example; however, this is non-limiting. For example, the switch device 20 may be disposed closer to the bit line BL, and the memory device 30 may be disposed closer to the word line WL. Further, in a case where the switch device 20 is disposed closer to the word line WL and the memory device 30 is disposed closer to the bit line BL in a certain layer, the switch device 20 may be disposed closer to the bit line BL and the memory device 30 may be disposed closer to the word line WL in a layer adjacent to that layer. Further, in each layer, the memory device 30 may be provided on top of the switch device 20, or conversely, the switch device 20 may be provided on top of the memory device 30.

Further, in the memory cell array 1 of the present embodiment, for example, a non-volatile memory (NVM: Non-Volatile Memory) such as an OTP (One Time Programable) memory device that allows for only one-time writing using a fuse or an anti-fuse, a unipolar phase-change memory device, a resistance-change memory device, or a magnetoresistive memory device is usable as the memory device 30.

### 1-3. Workings and Effects

The switch device 20 of the present embodiment includes the switch layer 22 including the first element selected from Ge and Si, the second element selected from As, P, and Sb, and the third element selected from Se and Te. The switch layer 22 has the stacked structure in which at least one first layer 22A and at least one second layer 22B are stacked. The first layer 22A includes, among the three kinds of elements described above, at least one kind of the second element and at least one kind of the third element, includes the third element in the range of 50 atomic % or more and 80 atomic % or less in composition ratio, and has the negative temperature dependence of the threshold voltage. The second layer 22B includes, among the three kinds of elements described above, at least one kind of the first element and at least one kind of the third element, includes the first element in the range of 20 atomic % or more and 50 atomic % or less in composition ratio, and has the positive temperature dependence of the threshold voltage. This reduces the dependence, of the threshold voltage (Vₜₕ) and the threshold electric field (Fₜₕ) at which the switch device 20 switches between on and off states, on the ambient temperature. This will be described below.

In recent years, a larger capacity has been demanded of a non-volatile memory for data storage typified by a resistance change type memory, such as a ReRAM (Resistance Random Access Memory) or a PRAM (Phase-Change Random Access Memory) (registered trademark), and a memory cell array adopting the so-called cross-point array structure in which memory devices are disposed at points of intersection (cross-points) between intersecting wiring lines has been developed. In a cross-point memory cell array, a switch device for cell selection is provided in addition to the memory device.

Incidentally, the threshold voltage of the switch device and the memory device has a property of decreasing with increasing ambient temperature. Accordingly, in order to allow the cross-point memory cell array to operate normally, a large-scale control circuit is provided that adjusts a voltage to be applied to the bit lines and the word lines of the memory cell array while monitoring the ambient temperature. However, the large-scale control circuit leads to degradation in memory integration efficiency due to a heavy load being placed on a voltage compensation circuit, and thus becomes a factor contributing to a decrease in memory capacity and an increase in cost.

In contrast, according to the present embodiment, the switch layer 22 is provided between the lower electrode 21 and the upper electrode 23, the switch layer 22 having the stacked structure in which at least one first layer 22A and at least one second layer 22B that include the above-described first to third elements at a predetermined ratio are stacked. Specifically, the first layer 22A includes, among the three kinds of elements described above, at least one kind of the second element and at least one kind of the third element, includes the third element in the range of 50 atomic % or more and 80 atomic % or less in composition ratio, and has the negative temperature dependence of the threshold voltage. The second layer 22B includes, among the three kinds of elements described above, at least one kind of the first element and at least one kind of the third element, includes the first element in the range of 20 atomic % or more and 50 atomic % or less in composition ratio, and has the positive temperature dependence of the threshold voltage (Vₜₕ). This reduces the dependence, of the threshold voltage (Vₜₕ) and the threshold electric field (Fₜₕ) at which the switch device 20 switches between on and off states, on the ambient temperature.

By virtue of the foregoing, according to the switch device 20 of the present embodiment and the memory cell array 1 including the switch device 20, it becomes unnecessary to provide the large-scale control circuit that adjusts the voltage to be applied to the bit lines and the word lines of the memory cell array in accordance with the ambient temperature. This makes it possible to improve the integration efficiency of the memory cells, thus making it possible to provide a larger-capacity memory cell array.

Next, a description will be given of a second embodiment and a modification example. In the following description, components similar to those of the foregoing first embodiment are assigned the same reference signs, and descriptions thereof are omitted as appropriate.

### 2. Second Embodiment

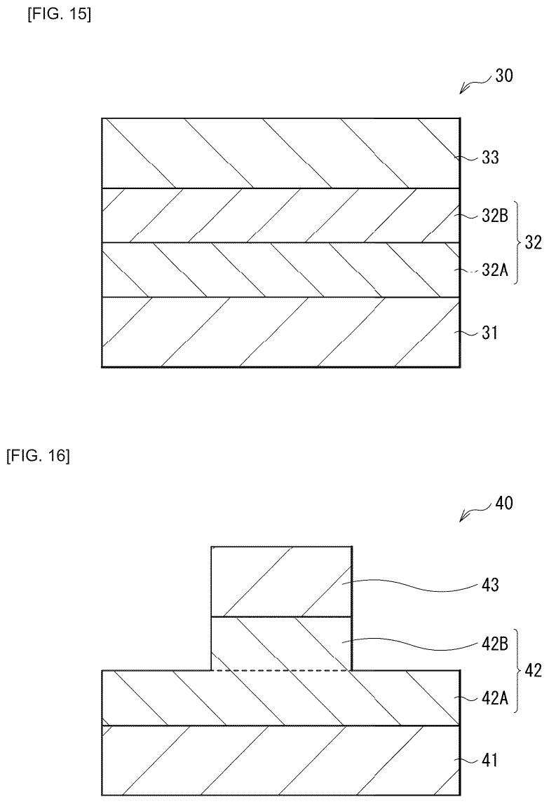

FIG. 16 schematically illustrates an example of a cross-sectional configuration of a switch device (a switch device 40) according to the second embodiment of the present disclosure. This switch device 40 is provided to selectively operate, for example, any memory device (the memory device 30) among multiple memory devices provided in the memory cell array 1 having the so-called cross-point array structure illustrated in FIG. 2. The switch device 40 is coupled in series to the memory device 30 (specifically, the memory layer 32), and includes a lower electrode 41, a switch layer 42, and an upper electrode 43 in this order. The switch layer 42 of the present embodiment has different diameters in a stacking direction.

The lower electrode 41 corresponds to a specific example of the “first electrode” in the present disclosure. As with the lower electrode 21 of the first embodiment described above, the lower electrode 41 may include a wiring line material to be used in a semiconductor process, for example. Specifically, the lower electrode 31 may include, for example, W, WN, TiN, Cu, Al, Mo, Ta, TaN, silicide, or the like. In a case where the lower electrode 31 includes a material that can cause ion conduction in an electric field, such as Cu, a front surface of the lower electrode 31 may be coated with a material that is unlikely to cause ion conduction or thermal diffusion. Examples of the material that is unlikely to cause ion conduction or thermal diffusion include W, WN, TiN, TaN, TiW, TiWN, and the like.

The switch layer 42 has the different diameters in the stacking direction, as described above. Specifically, the switch layer 42 includes, in the stacking direction, a first region 42A having a first diameter and a second region 42B having a second diameter smaller than the first diameter. The switch layer 42 includes a first element selected from Ge and Si, a second element selected from As, P, and Sb, and a third element selected from Se and Te, as described above.

As described in the foregoing first embodiment, the thermal conductivity (K) is proportional to the third power of the Debye temperature (Tp). Therefore, by preparing two layers (layer C and layer D) that are different in size (diameter of the thin film) in a direction (radial direction) orthogonal to the stacking direction, it is possible to modulate the Debye temperature (T_{D}) of each layer, as indicated in mathematical expression (9).

### Example 2

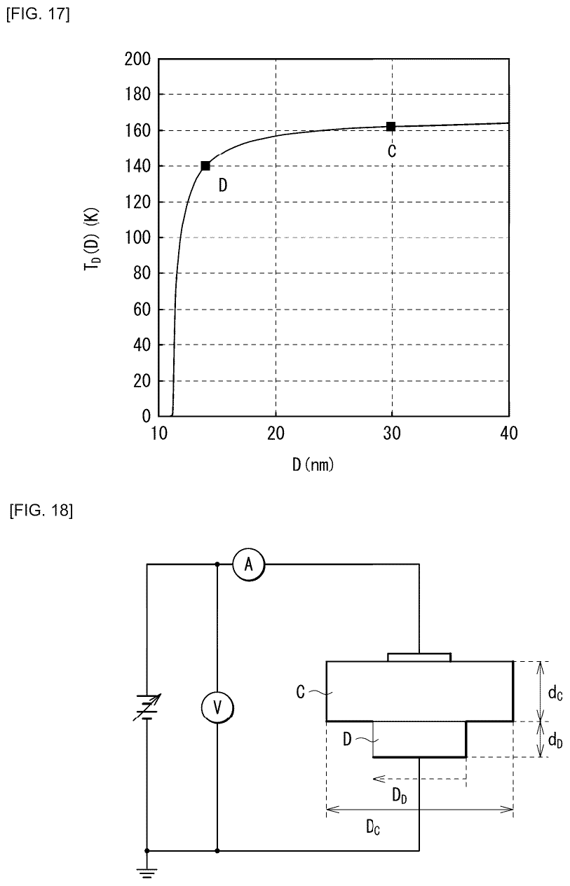

FIG. 17 illustrates a size dependence (T_{D}(D)) of the Debye temperature (T_{D}) of a thin film of a composition ratio of As₄₀Se₆₀. In Example 2, the layer C (corresponding to the first region 42A) and the layer D (corresponding to the second region 42B) were formed in order by co-sputtering. The layer C had the composition ratio of As₄₀Se₆₀, a film thickness (d_{C}) of 14 nm, and a diameter (D_{C}) of 20 nm. The layer D had the composition ratio of As₄₀Se₆₀, a film thickness (d_{D}) of 7 nm, and a diameter (D_{D}) of 4 nm. FIG. 18 schematically illustrates an experimental apparatus used in Example 2. It is seen that the difference in diameter produces a difference in Debye temperature (T_{D}) by about 10%. Because the size dependence of the Debye temperature (T_{D}) is very sharp as can be seen from FIG. 17, a border between size C and size D is estimated to be at about 10 nm.

Based upon the above, the diameter (the first diameter) of the first region 42A of the switch layer 42 is preferably 10 nm or more. The diameter (the second diameter) of the second region 42B of the switch layer 42 is preferably less than 10 nm. This allows the Debye temperature (T_{D}) of the second region 42B to be 90% or less relative to the Debye temperature (T_{D}) of the first region 42A, thus making it possible to reduce the ambient temperature dependence of the threshold voltage (Vₜₕ) expressed by mathematical expression (10) described above.

The switch layer 42 preferably has a film thickness of 15 nm or more and 75 nm or less, for example. Of the switch layer 42, the first region 42A preferably has a film thickness of 5 nm or more and 25 nm or less, for example, and the second region 42B preferably has a film thickness of 10 nm or more and 50 nm or less, for example.

Besides the above-described configuration of the switch device 40, the switch device 40 of the present embodiment may have the following configurations.

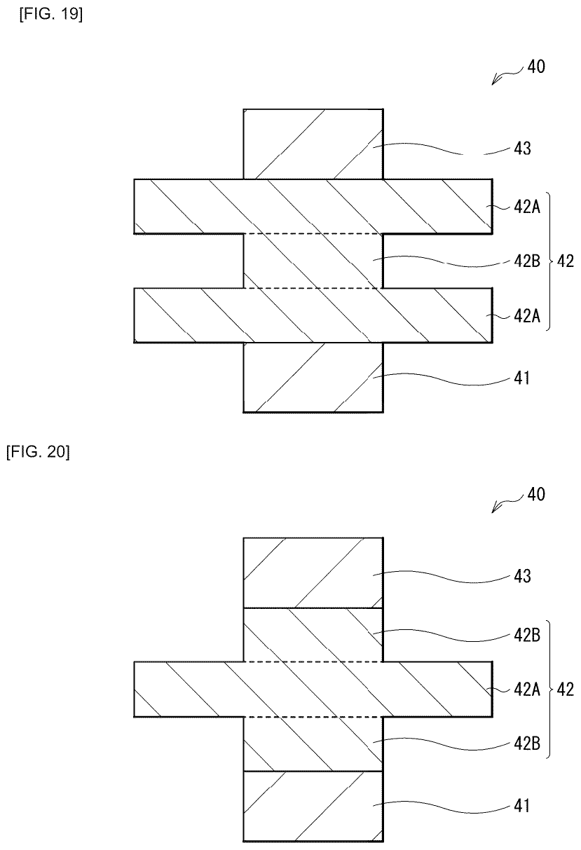

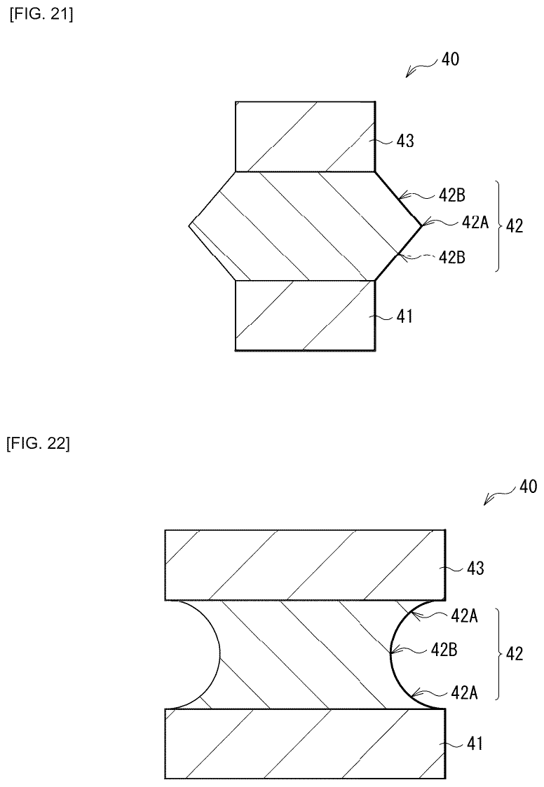

For example, the switch device 40 may have a configuration in which two or more first regions 42A and two or more second regions 42B configuring the switch layer 42 are stacked. For example, as illustrated in FIG. 19, the switch layer 42 may have a configuration in which the first region 42A, the second region 42B, and the first region 42A are stacked in this order from the lower electrode 21 side. For example, as illustrated in FIG. 20, the switch layer 42 may have a configuration in which the second region 42B, the first region 42A, and the second region 42B are stacked in this order from the lower electrode 21 side. Further, the diameter of the switch layer 42 may deform stepwise as illustrated in FIGS. 16, 19, and 20, or may change continuously as illustrated in FIGS. 21 and 22, for example.

The upper electrode 23 corresponds to a specific example of the “second electrode” in the present disclosure. As with the upper electrode 23 of the foregoing first embodiment, the upper electrode 23 may include, for example, a known semiconductor wiring line material similarly to the lower electrode 21: however, it is preferable to use a stable material that does not react with the switch layer 22 even after undergoing post-annealing. Specifically, the upper electrode 23 may include tungsten (W), for example.

As described above, in the switch device 40 of the present embodiment, the switch layer 42 having different diameters in the stacking direction is provided between the lower electrode 21 and the upper electrode 23. This reduces the dependence, of the threshold voltage (Vₜₕ) and the threshold electric field (Fₜₕ) at which the switch device 40 switches between on and off states, on the ambient temperature. Accordingly, in the memory cell array 1 including the switch device 40, it becomes unnecessary to provide the large-scale control circuit that adjusts the voltage to be applied to the bit lines and the word lines of the memory cell array in accordance with the ambient temperature. This makes it possible to improve the integration efficiency of the memory cells, thus making it possible to provide a larger-capacity memory cell array.

It is to be noted that the configuration of the switch device 40 of the present embodiment is applicable to a memory device (e.g., the memory device 30) included in the memory cell 10 illustrated in FIG. 2 or the like. That is, as in the switch device 40 of the present embodiment, a memory layer (e.g., the memory layer 32) may be provided as a layer having different diameters in the stacking direction.

### 3. Modification Example

Regarding the memory cell array 1 of the foregoing embodiments, the example has been given in which the multiple word lines WL extending in a Y-axis direction and the multiple bit lines BL extending in an X-axis direction are divided into multiple layers and are alternately disposed, and the memory cell 10 is disposed at each of the cross-points; however, this is non-limiting. The switch device (e.g., the switch device 20) of the present disclosure and the memory cell 10 including the switch device are also applicable to a memory cell array having a three-dimensional structure as described below, for example.

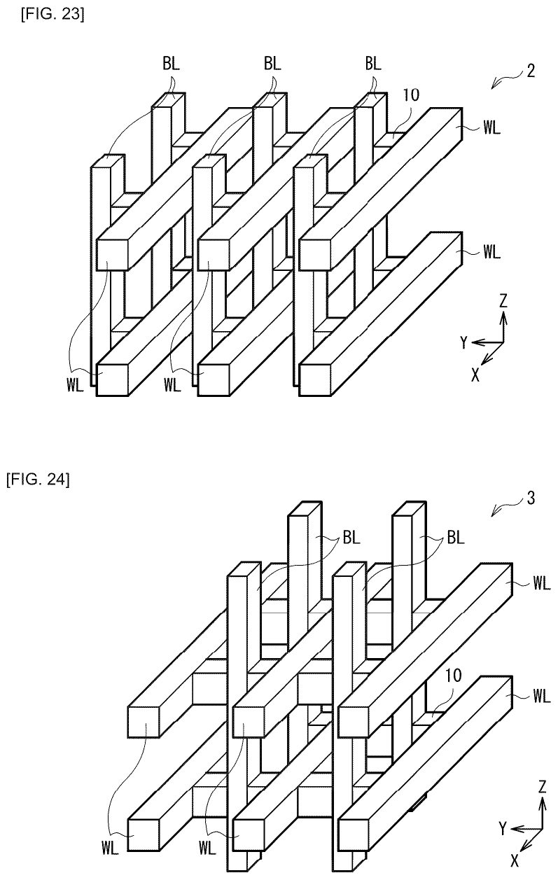

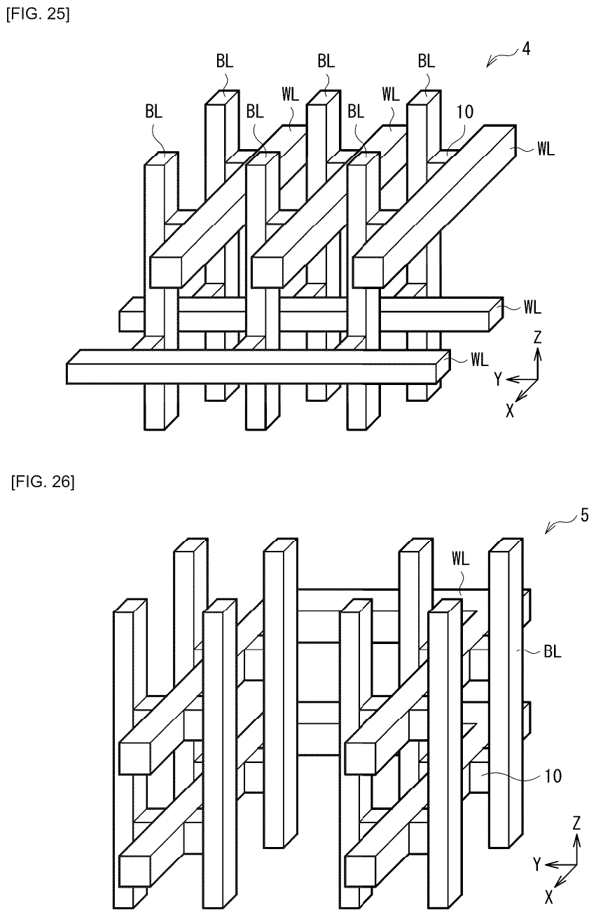

A memory cell array 2 illustrated in FIG. 23 includes the multiple word lines WL that each extend in the X-axis direction, the multiple bit lines BL that each extend in the Z-axis direction, and the memory cell 10 disposed at each of the cross-points. A memory cell array 3 illustrated in FIG. 24 includes the memory cell 10 disposed on each of both surfaces of cross-points between the multiple word lines WL and the multiple bit lines BL that extend in the X-axis direction and the Z-axis direction, respectively, as with the memory cell array 2. A memory cell array 4 illustrated in FIG. 25 includes the multiple bit lines BL that extend in the Z-axis direction and two types of multiple word lines WL that extend in two directions, i.e., the X-axis direction and the Y-axis direction, and the memory cell 10 disposed at each of the cross-points. A memory cell array 5 illustrated in FIG. 26 includes the multiple bit lines BL that extend in the Z-axis direction, the multiple word lines WL that extend in the X-axis direction, bend midway into the Y-axis direction, and further bend into the X-axis direction to thereby extend into a so-called U-shape in an X-Y plane, and the memory cell 10 disposed at each of the cross-points.

As has been described, the switch devices 20 and 40 of the foregoing first and second embodiments and the memory cells 10 including the respective switch devices are also applicable to a so-called vertical cross-point-structured memory cell array (e.g., any of the memory cell arrays 2 to 5) in which either one of the word line WL or the bit line BL is provided in parallel to the Z-axis direction and the other thereof is provided in parallel to the X-Y plane direction. In addition, as in the memory cell array 5 illustrated in FIG. 26, for example, the multiple word lines WL and the multiple bit lines BL do not necessarily have to extend in one direction.

Although the present disclosure has been described above with reference to the first and second embodiments and the modification example thereof, the present disclosure is not limited to the above-described embodiments and the like, and is modifiable in a variety of ways.

It is to be noted that the effects described in the present specification are merely examples and non-limiting, and there may be other effects as well.

It is to be noted that the present disclosure may also have the following configurations. According to the technology having the following configurations, the switch layer including the first element selected from germanium and silicon, the second element selected from arsenic, phosphorus, and antimony, and the third element selected from selenium and tellurium is provided between the first electrode and the second electrode. Among the components, the switch layer of the first switch device includes at least one first layer and at least one second layer that are stacked. The first layer includes at least one kind of the second element and at least one kind of the third element, includes the third element in the range of 50 atomic % or more and 80 atomic % or less in composition ratio, and is negative in temperature dependence of the threshold voltage. The second layer includes at least one kind of the first element and at least one kind of the third element, includes the first element in the range of 20 atomic % or more and 50 atomic % or less in composition ratio, and is positive in temperature dependence of the threshold voltage. The switch layer of the second switch device has different diameters in the stacking direction. This reduces the dependence, of the threshold voltage and the threshold electric field at which the switch device switches between on and off states, on the ambient temperature. Accordingly, it is possible to improve the integration efficiency of the memory cells.

[1]

A switch device including:
a first electrode;
a second electrode disposed to be opposed to the first electrode; and
a switch layer provided between the first electrode and the second electrode and including a first element selected from germanium and silicon, a second element selected from arsenic, phosphorus, and antimony, and a third element selected from selenium and tellurium, in which
the switch layer includes at least one first layer and at least one second layer that are stacked,
the first layer includes at least one kind of the second element and at least one kind of the third element, includes the third element in a range of 50 atomic % or more and 80 atomic % or less in composition ratio, and is negative in temperature dependence of a threshold voltage, and
the second layer includes at least one kind of the first element and at least one kind of the third element, includes the first element in a range of 20 atomic % or more and 50 atomic % or less in composition ratio, and is positive in temperature dependence of the threshold voltage.
   [2]

The switch device according to [1], in which the first layer and the second layer each include the second element in a range of 0 atomic % or more and 50 atomic % or less in composition ratio.

[3]

The switch device according to [1] or [2], in which the switch layer further includes, as an impurity, at least one of boron, aluminum, gallium, or indium.

[4]

The switch device according to any one of [1] to [3], in which the switch layer further includes a third layer that satisfies mathematical expression (1) below:

$$\begin{matrix}[ Math . 1 ] & \\ \frac{{k}_{B} A ( T )}{e} \frac{η {ϕ}_{B} - {F}_{th} d}{η {V}_{t}^{2}} {F}_{th}^{2} \times \frac{{d}^{2}}{κ} = 1 & ( 1 )\end{matrix}$$

where k_{B} represents Boltzmann constant, A(T) represents proportionality constant (A/cm²), ϕ_{B} represents barrier height (eV), Fₜₕ represents threshold electric field (MV/cm), d represents film thickness, Vt represents thermal voltage, and κ represents thermal conductivity.
[5]

The switch device according to any one of [1] to [4], in which the switch layer has a film thickness of 15 nm or more and 150 nm or less.

[6]

The switch device according to any one of [1] to [4], in which the first layer has a film thickness of 5 nm or more and 50 nm or less, and the second layer has a film thickness of 10 nm or more and 100 nm or less.

[7]

The switch device according to any one of [1] to [6], in which the switch layer changes into a low-resistance state by making an applied voltage higher than or equal to a predetermined threshold voltage, and changes into a high-resistance state by making the applied voltage lower than the threshold voltage, without involving a phase change between a non-crystalline phase and a crystalline phase.

[8]

A switch device including:
a first electrode;
a second electrode disposed to be opposed to the first electrode; and
a switch layer having different diameters in a stacking direction.
   [9]

The switch device according to [8], in which the switch layer has a first diameter, and a second diameter smaller than the first diameter.

[10]

The switch device according to [9], in which the switch layer includes a first region having the first diameter and a second region having the second diameter.

[11]

The switch device according to [9] or [10], in which the first diameter and the second diameter change from one to another continuously in the stacking direction.

[12]

The switch device according to [9] or [10], in which the first diameter and the second diameter change from one to another stepwise in the stacking direction.

[13]

The switch device according to any one of [9] to [12], in which the first diameter is a diameter of 10 nm or more and 100 nm or less, and the second diameter is 2 nm or more and 10 nm or less.

[14]

The switch device according to any one of [9] to [13], in which the switch layer includes a first element selected from germanium and silicon, a second element selected from arsenic, phosphorus, and antimony, and a third element selected from selenium and tellurium.

[15]

A memory unit including
multiple memory cells, in which
the multiple memory cells each include a memory device, and a switch device directly coupled to the memory device,
the switch device includes:
   a first electrode;
   a second electrode disposed to be opposed to the first electrode; and
   a switch layer provided between the first electrode and the second electrode and including a first element selected from germanium and silicon, a second element selected from arsenic, phosphorus, and antimony, and a third element selected from selenium and tellurium,
   the switch layer includes at least one first layer and at least one second layer that are stacked,
   the first layer includes at least one kind of the second element and at least one kind of the third element, includes the third element in a range of 50 atomic % or more and 80 atomic % or less in composition ratio, and is negative in temperature dependence of a threshold voltage, and
   the second layer includes at least one kind of the first element and at least one kind of the third element, includes the first element in a range of 20 atomic % or more and 50 atomic % or less in composition ratio, and is positive in temperature dependence of the threshold voltage.
      [16]

The memory unit according to [15], in which the memory device includes any one of a phase-change memory device, a resistance-change memory device, and a magnetoresistive memory device.

[17]

The memory unit according to or [16], in which
the memory device includes a third electrode, a fourth electrode disposed to be opposed to the third electrode, and a memory layer provided between the third electrode and the fourth electrode and including the first element, the second element, and the third element,
the memory layer includes at least one third layer and at least one fourth layer that are stacked,
the third layer includes at least one kind of the second element and at least one kind of the third element, includes the third element in the range of 50 atomic % or more and 80 atomic % or less in composition ratio, and is negative in temperature dependence of the threshold voltage, and
the fourth layer includes at least one kind of the first element and at least one kind of the third element, includes the first element in the range of 20 atomic % or more and 50 atomic % or less in composition ratio, and is positive in temperature dependence of the threshold voltage.
   [18]

The memory unit according to any one of [15] to [17], in which the memory device includes a third electrode, a fourth electrode disposed to be opposed to the third electrode, and a memory layer having different diameters in a stacking direction.

[19]

A memory device including:
a third electrode;
a fourth electrode disposed to be opposed to the third electrode; and
a memory layer provided between the third electrode and the fourth electrode and including a first element selected from germanium and silicon, a second element selected from arsenic, phosphorus, and antimony, and a third element selected from selenium and tellurium, in which
the memory layer includes at least one third layer and at least one fourth layer that are stacked,
the third layer includes at least one kind of the second element and at least one kind of the third element, includes the third element in a range of 50 atomic % or more and 80 atomic % or less in composition ratio, and is negative in temperature dependence of a threshold voltage, and
the fourth layer includes at least one kind of the first element and at least one kind of the third element, includes the first element in a range of 20 atomic % or more and 50 atomic % or less in composition ratio, and is positive in temperature dependence of the threshold voltage.
   [20]

A memory device including:
a third electrode;
a fourth electrode disposed to be opposed to the third electrode; and
a memory layer having different diameters in a stacking direction.

The present application claims the benefit of Japanese Priority Patent Application JP2021-007528 filed with the Japan Patent Office on Jan. 20, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A switch device comprising:
a first electrode;
a second electrode disposed to be opposed to the first electrode; and
a switch layer provided between the first electrode and the second electrode and including a first element selected from germanium and silicon, a second element selected from arsenic, phosphorus, and antimony, and a third element selected from selenium and tellurium, wherein
the switch layer includes at least one first layer and at least one second layer that are stacked,
the first layer includes at least one kind of the second element and at least one kind of the third element, includes the third element in a range of 50 atomic % or more and 80 atomic % or less in composition ratio, and is negative in temperature dependence of a threshold voltage, and
the second layer includes at least one kind of the first element and at least one kind of the third element, includes the first element in a range of 20 atomic % or more and 50 atomic % or less in composition ratio, and is positive in temperature dependence of the threshold voltage.

2. The switch device according to claim 1, wherein the first layer and the second layer each include the second element in a range of 0 atomic % or more and 50 atomic % or less in composition ratio.

3. The switch device according to claim 1, wherein the switch layer further includes, as an impurity, at least one of boron, aluminum, gallium, or indium.

4. The switch device according to claim 1, wherein the switch layer further includes a third layer that satisfies mathematical expression (1) below:
$$\begin{matrix}[ Math . 1 ] & \\ \frac{{k}_{B} A ( T )}{e} \frac{η {ϕ}_{B} - {F}_{th} d}{η {V}_{t}^{2}} {F}_{th}^{2} \times \frac{{d}^{2}}{κ} = 1 & ( 1 )\end{matrix}$$
where k_{B} represents Boltzmann constant, A(T) represents proportionality constant (A/cm²), ϕ_{B} represents barrier height (eV), Fₜₕ represents threshold electric field (MV/cm), d represents film thickness, Vt represents thermal voltage, and κ represents thermal conductivity.

5. The switch device according to claim 1, wherein the switch layer has a film thickness of 15 nm or more and 150 nm or less.

6. The switch device according to claim 1, wherein the first layer has a film thickness of 5 nm or more and 50 nm or less, and the second layer has a film thickness of 10 nm or more and 100 nm or less.

7. The switch device according to claim 1, wherein the switch layer changes into a low-resistance state by making an applied voltage higher than or equal to a predetermined threshold voltage, and changes into a high-resistance state by making the applied voltage lower than the threshold voltage, without involving a phase change between a non-crystalline phase and a crystalline phase.

8. A switch device comprising:
a first electrode;
a second electrode disposed to be opposed to the first electrode; and
a switch layer having different diameters in a stacking direction.

9. The switch device according to claim 8, wherein the switch layer has a first diameter, and a second diameter smaller than the first diameter.

10. The switch device according to claim 9, wherein the switch layer includes a first region having the first diameter and a second region having the second diameter.

11. The switch device according to claim 9, wherein the first diameter and the second diameter change from one to another continuously in the stacking direction.

12. The switch device according to claim 9, wherein the first diameter and the second diameter change from one to another stepwise in the stacking direction.

13. The switch device according to claim 9, wherein the first diameter is a diameter of 10 nm or more and 100 nm or less, and the second diameter is 2 nm or more and 10 nm or less.

14. The switch device according to claim 8, wherein the switch layer includes a first element selected from germanium and silicon, a second element selected from arsenic, phosphorus, and antimony, and a third element selected from selenium and tellurium.

15. A memory unit comprising
multiple memory cells, wherein
the multiple memory cells each include a memory device, and a switch device directly coupled to the memory device,
the switch device includes:
a first electrode;
a second electrode disposed to be opposed to the first electrode; and
a switch layer provided between the first electrode and the second electrode and including a first element selected from germanium and silicon, a second element selected from arsenic, phosphorus, and antimony, and a third element selected from selenium and tellurium,
the switch layer includes at least one first layer and at least one second layer that are stacked,
the first layer includes at least one kind of the second element and at least one kind of the third element, includes the third element in a range of 50 atomic % or more and 80 atomic % or less in composition ratio, and is negative in temperature dependence of a threshold voltage, and
the second layer includes at least one kind of the first element and at least one kind of the third element, includes the first element in a range of 20 atomic % or more and 50 atomic % or less in composition ratio, and is positive in temperature dependence of the threshold voltage.

16. The memory unit according to claim 15, wherein the memory device comprises any one of a phase-change memory device, a resistance-change memory device, and a magnetoresistive memory device.

17. The memory unit according to claim 15, wherein
the memory device includes a third electrode, a fourth electrode disposed to be opposed to the third electrode, and a memory layer provided between the third electrode and the fourth electrode and including the first element, the second element, and the third element,
the memory layer includes at least one third layer and at least one fourth layer that are stacked,
the third layer includes at least one kind of the second element and at least one kind of the third element, includes the third element in the range of 50 atomic % or more and 80 atomic % or less in composition ratio, and is negative in temperature dependence of the threshold voltage, and
the fourth layer includes at least one kind of the first element and at least one kind of the third element, includes the first element in the range of 20 atomic % or more and 50 atomic % or less in composition ratio, and is positive in temperature dependence of the threshold voltage.

18. The memory unit according to claim 15, wherein the memory device includes a third electrode, a fourth electrode disposed to be opposed to the third electrode, and a memory layer having different diameters in a stacking direction.
